(19) United States
(12) Patent Application Publication
(10) Pub. No.: US 2019/0363145 A1
(43) Pub. Date: Nov. 28, 2019

(54) OLED PANEL, METHOD FOR PRODUCING OLED PANEL, AND APPARATUS FOR PRODUCING OLED PANEL

(71) Applicant: Sharp Kabushiki Kaisha, Sakai City, Osaka (JP)

(72) Inventors: Yoshifumi OHTA, Sakai City (JP); Tohru SONODA, Sakai City (JP)

(21) Appl. No.: 16/064,072

(22) PCT Filed: Jan. 26, 2017
(86) PCT No.: PCT/JP2017/002691

§ 371 Date: Jun. 20, 2018

(51) Int. Cl. H01L 27/32; H01L 51/52; H01L 51/00; H01L 51/56

(52) U.S. Cl. CPC H01L 27/3246; H01L 51/5253; H01L 51/56; H01L 51/0097; H01L 27/3276

(57) ABSTRACT

A base substrate, a OLED element, and a seal portion covering the OLED element are included. The seal portion includes a first sealing film including an inorganic film, a second sealing film including an organic film, a third sealing film including an inorganic film, and a coupling layer formed between the first sealing film and the second sealing film.

### TECHNICAL FIELD

The disclosure relates to an organic light emitting diode (OLED) panel.

### BACKGROUND ART

PTL 1 discloses a structure in which OLED elements are surrounded by inorganic films and an organic film formed on the inorganic film so that penetration of moisture and oxygen into the OLED elements can be prevented.

### CITATION LIST

### Patent Literature

PTL 1: JP 2016-54144 A (published on Apr. 14, 2016)

### SUMMARY

### Technical Problem

One problem with the structure disclosed in PTL 1 is that forming the organic film to a desired shape (e.g., thickness and area) is difficult.

### Solution to Problem

According to an embodiment of the disclosure, an OLED panel includes a base substrate, an OLED element, and a seal portion covering the OLED element. The seal portion includes a first sealing film including an inorganic film, a second sealing film including an organic film, a third sealing film including an inorganic film, and a coupling layer formed between the first sealing film and the second sealing film.

According to an embodiment of the disclosure, a method for producing an OLED panel is provided. The OLED panel includes a base substrate, an OLED element, and a seal portion. The seal portion includes a first sealing film including an inorganic film, and a second sealing film including an organic film. The method includes forming a coupling layer on the first sealing film and forming, by an ink-jet method, a second sealing film on the coupling layer.

### Advantageous Effects of Disclosure

The coupling layer, included in the seal portion, makes it easier to form the second sealing film, which is an organic film, to a desired shape (e.g., thickness and area).

### BRIEF DESCRIPTION OF DRAWINGS

FIG. 1 is a plan view illustrating a configuration of a display device according to the present embodiment.

FIG. 2 is a cross-sectional view of the display device of FIG. 1 taken along line a-a and viewed in the direction of the arrows.

FIG. 3 is a cross-sectional view of the display device of FIG. 1 taken along line b-b and viewed in the direction of the arrows.

FIG. 4 is a flowchart illustrating a process of forming a seal portion.

FIG. 5 is a plan view illustrating another configuration of the display device according to the present embodiment.

FIG. 6 is a cross-sectional view of the display device of FIG. 5 taken along line c-c and viewed in the direction of the arrows.

FIG. 7 is a plan view illustrating a modified example of the display device of FIG. 1.

FIG. 8 is a plan view illustrating still another configuration of the display device according to the present embodiment.

FIG. 9 is a cross-sectional view of the display device of FIG. 8 taken along line e-e and viewed in the direction of the arrows.

FIG. 10 is a plan view illustrating a modified example of the display device illustrated in FIGS. 8 and 9.

FIG. 11 is a plan view illustrating still another configuration of the display device according to the present embodiment.

### DESCRIPTION OF EMBODIMENTS

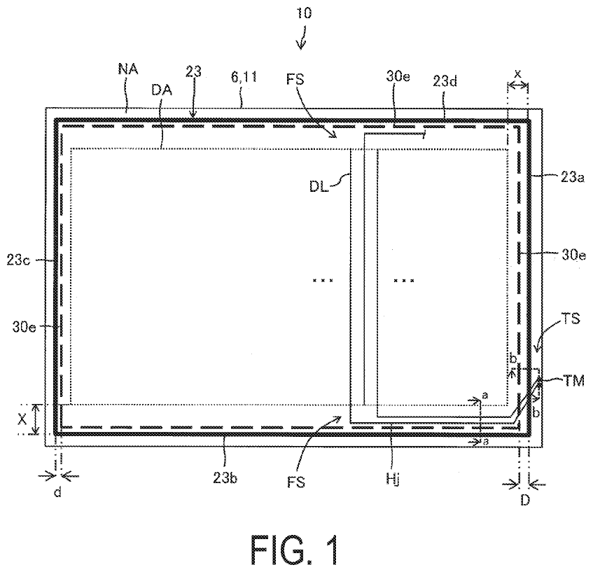

Embodiments of the disclosure will be described below with reference to FIGS. 1 to 11. These embodiments are merely illustrative.

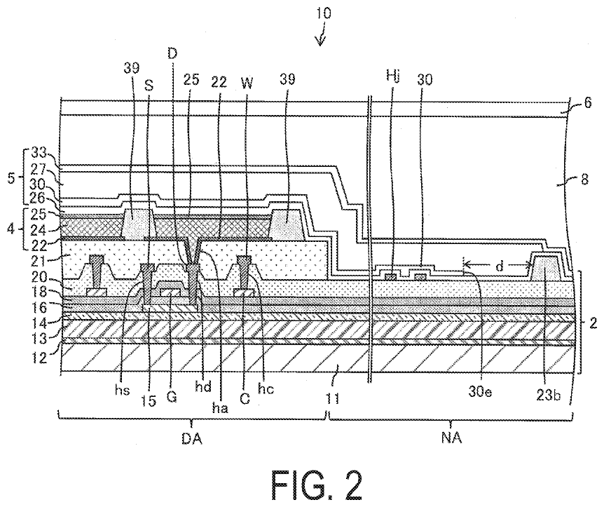

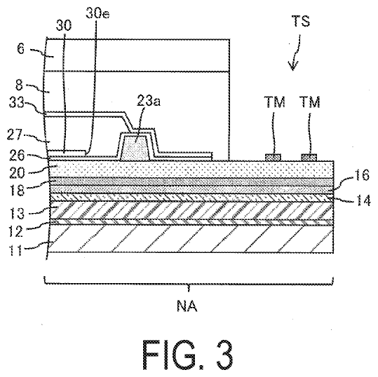

FIG. 1 is a plan view illustrating a configuration of a display device according to the present embodiment. FIG. 2 is a cross-sectional view of the display device of FIG. 1 taken along line a-a and viewed in the direction of the arrows. FIG. 3 is a cross-sectional view of the display device of FIG. 1 taken along line b-b and viewed in the direction of the arrows.

As illustrated in FIGS. 1 and 2, the display device 10 includes an OLED panel 2, which includes a base substrate 11 and OLED elements 4, and a functional film 6 bonded to the upper surface of the OLED panel 2 via an adhesive layer 8. The OLED panel 2 includes a display area DA and a non-display area NA. Pixels including the organic light emitting diode (OLED) elements 4 are provided in the display are DA. The non-display area NA surrounds the display area DA. The following descriptions are provided assuming that the direction from the base substrate 11 toward the OLED elements 4 is the upward direction. Furthermore, areas at or relatively near the display area DA in plan view may be referred to as inside, and areas at or relatively near the edge of the panel in plan view may be referred to as outside.

The OLED panel 2 includes a base substrate 11, an adhesive layer 12, a resin layer 13, a moisture-proof layer 14, semiconductor films 15, a gate insulator film 16, gate electrodes G, a first interlayer insulating film 18, capacitive electrodes C, a second interlayer insulating film 20, source electrodes S, drain electrodes D, wires W, a flattering film 21, anode electrodes 22, a partition 39, a bank 23 (23a to 23d), organic EL (organic electroluminescent) layers 24, cathode electrodes 25, a first sealing film 26, a coupling layer 30, a second sealing film 27, and a third sealing film 33. The resin layer 13 is bonded to the base substrate 11 via the adhesive layer 12. The moisture-proof layer 14 is formed on the resin layer 13. The semiconductor films 15 are formed on the moisture-proof layer 14. The gate insulator film 16 is formed on the semiconductor films 15. The gate electrodes G are formed on the gate insulator film 16. The first interlayer insulating film 18 covers the gate electrodes G. The capacitive electrodes C are formed on the first interlayer insulating film 18. The second interlayer insulating film 20 covers the capacitive electrodes C. The source electrodes S, the drain electrodes D, and the wires W are formed on the second interlayer insulating film 20. The flattering film 21 covers the source electrode S, the drain electrodes D, and the wires W. The anode electrodes 22 are formed on the flattering film 21. The partition 39 defines pixels for the colors. The bank 23 (23a to 23d) is formed in the non-display area NA. The organic EL layers 24 are formed on the anode electrodes 22. The cathode electrodes 25 are formed on the organic EL layers 24. The first sealing film 26 covers the partition 39 and the cathode electrodes 25. The coupling layer 30 is formed on the first sealing film 26. The second sealing film 27 covers the coupling layer 30. The third sealing film 33 covers the second sealing film 27. The coupling layer 30 is light-transmissive, for example.

The base substrate 11 is formed of an insulating flexible material, for example. The resin layer 13 is formed of polyimide, for example. The moisture-proof layer 14 is formed of silicon oxide (SiOx), silicon nitride (SiNx), or composed of layered films of these materials, for example. The semiconductor film 15 is formed of amorphous silicon, polysilicon, or an oxide semiconductor, for example. The gate insulator film 16 is formed of silicon oxide (SiOx), silicon nitride (SiNx), or composed of layered films of these materials, for example. The gate electrode G, the source electrode S, the drain electrode D, the capacitive electrode C, and the wire W, are each composed of a single layer metal film or a layered metal film, for example. The metal is at least one metal selected from aluminum (Al), tungsten (W), molybdenum (Mo), tantalum (Ta), chromium (Cr), titanium (Ti), and copper (Cu), for example.

The first interlayer insulating film 18 and the second interlayer insulating film 20 may each be formed of, for example, silicon oxide (SiOx) or silicon nitride (SiNx). The flattering film 21 may be formed of a coatable photosensitive organic material, such as a polyimide material or an acrylic material. The anode electrode 22 is formed by, for example, layering an Indium Tin Oxide (ITO) layer and a Ag alloy layer. The anode electrode 22 is light-reflective.

The semiconductor film 15, the gate insulator film 16, the gate electrode G, the first interlayer insulating film 18, the second interlayer insulating film 20, the source electrode S, and the drain electrode D form a thin film transistor (TFT). The semiconductor film 15 and the source electrode S are connected to each other via a contact hole hs extending through the gate insulator film 16, the first interlayer insulating film 18, and the second interlayer insulating film 20. The source electrode S is connected to a power source line (not illustrated), for example. The semiconductor film 15 and the drain electrode D are connected to each other via a contact hole hd extending through the gate insulator film 16, the first interlayer insulating film 18, and the second interlayer insulating film 20. The drain electrode D and the anode electrode 22 are connected to each other via a contact hole ha extending through the flattering film 21. The wire W and the capacitive electrode C are connected to each other via a contact hole he extending through the second interlayer insulating film 20.

The bank 23 and the partition 39 can be formed in the same step, for example, from a coatable photosensitive organic material, such as a polyimide material or an acrylic material. The flattering film 21 and the partition 39 are formed in the display area DA (not formed in the non-display area NA).

The bank 23 defines the edge of the second sealing film 27, and is formed on an upper side of the second interlayer insulating film 20, in the non-display area NA. The bank 23 has a shape of a single-walled rectangular frame and surrounds the display area DA. The bank 23 includes a first side 23a extending along the column direction (vertical direction in the drawing), a second side 23b extending along the row direction (lateral direction in the drawing), a third side 23c extending along the column direction (vertical direction in the drawing), and a fourth side 23d extending along the row direction. The length relationship is as follows: first side 23a=third side 23c<second side 23b=fourth side 23d. Another possible configuration of the bank is a frame shape formed by a plurality of independent islands (projections) arranged to surround the display area DA.

The organic EL layer 24 is formed in each of the regions surrounded by the partition 39 (subpixel regions), by a vapor deposition method or an ink-jet method. For example, the organic EL layer 24 is formed by layering, for example, a hole injecting layer, a hole transport layer, a light emitting layer, an electron transport layer, and an electron injecting layer in this order, with the hole injecting layer being the bottom layer. The cathode electrode 25 may be formed of transparent metal, such as Indium Tin Oxide (ITO) or Indium Zincum Oxide (IZO).

The anode electrode 22, the cathode electrode 25, and the organic EL layer 24, which is sandwiched therebetween, form the organic light emitting diode (OLED) element 4. In the OLED element 4, when a drive current flows between the anode electrode 22 and the cathode electrode 25, holes and electrons recombine in the light emitting layer to form excitons, and when the excitons fall to their ground state, light is emitted.

The first sealing film 26 and the third sealing film 33 are light-transmitting inorganic insulating films. The second sealing film 27 is a light-transmitting organic insulating film and is thicker than the first sealing film 26 and the third sealing film 33. The coupling layer 30 has an affinity for inorganic films and organic films. The first sealing film 26, the coupling layer 30, the second sealing film 27, and the third sealing film 33 are layered in this order, with the first sealing film 26 being closest to the OLED elements 4, to form a seal portion 5. The seal portion 5 covers the OLED elements 4 to prevent penetration of foreign matter, such as moisture and oxygen, into the OLED elements 4.

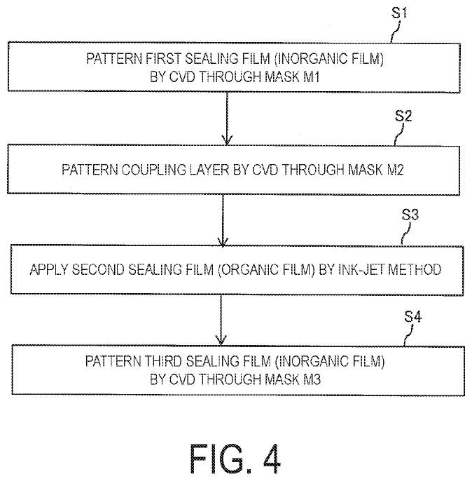

FIG. 4 is a flowchart illustrating a process of forming the seal portion. An apparatus for producing the OLED panel performs the following steps.

The first sealing film 26 may be formed of, for example, silicon oxide (SiOx), silicon nitride (SiNx), silicon oxynitride (SiON), or formed by layering films formed of these materials. The first sealing film 26 is patterned by performing chemical vapor deposition (CVD) film forming through a mask M1 (e.g., metal mask) (FIG. 4: step S1). The mask M1 is a separate member from the substrate on which the OLED elements 4 are formed. This process eliminates the need for photolithography processing, and thus reduces the possibility of degradation of the OLED elements 4 due to, for example, moisture and oxygen. The first sealing film 26 is formed to extend outside the bank 23b (toward the edge of the substrate).

The coupling layer 30 may be formed of, for example, an organosilicon compound, such as hexamethyldisiloxane or silicon carbon nitride (SiCN). The coupling layer 30 is also patterned by performing CVD film forming through a mask M2 (e.g., metal mask) (FIG. 4: step S2). The mask M2 is a separate member from the substrate on which the OLED elements 4 are formed. This process eliminates the need for photolithography processing, and thus reduces the possibility of degradation of the OLED elements 4 due to, for example, moisture and oxygen.

In step S2, the coupling layer 30 is formed to extend outside the display area DA (into the non-display area NA). An edge 30e of the coupling layer 30 is located inside the bank 23 so that a predetermined distance d can be provided between the edge of the coupling layer 30 and the bank 23. In the steps S1 and S2, the first sealing film 26 and the coupling layer 30 are successively formed by CVD. Since the patterns of the two films are different from each other as described above, the masks for use are to be changed (M1→M2).

In the display area, a plurality of data lines DL extend in the column direction (vertical direction in the drawing). A wiring section FS are provided to route the data lines DL. The wiring section FS is located outside the display area and inside the second side 23b of the bank 23. The coupling layer 30 overlaps the wiring section FS. The wiring section FS includes wiring section wires Hj, which are connected to the data lines DL. The coupling layer 30 covers the wiring section wires Hj via the first sealing film 26. It is also possible to provide the wiring section FS outside the second side 23b of the bank 23.

The second sealing film 27 is formed by, for example, applying ink including an organic photosensitive material, such as an acrylic material or an epoxy material, by an ink-jet method and curing the ink with UV light (FIG. 4: step S3). The flow of the ink can be stopped by the bank 23, so that the second sealing film 27 will not extend outside the bank 23. The use of an ink-jet method to apply the second sealing film 27 eliminates the need for photolithography processing to pattern the organic film. This reduces the possibility of degradation of the OLED elements 4 due to, for example, moisture and oxygen.

The third sealing film 33 may be formed of, for example, silicon oxide (SiOx), silicon nitride (SiNx), silicon oxynitride (SiON), or formed by layering films formed of these materials. The third sealing film 33 is patterned by performing CVD film forming through a mask M3 (e.g., metal mask) (FIG. 4: step S4). The mask M3 is a separate member from the substrate including the OLED elements 4. The mask M3 may have the same pattern as the mask M1.

As illustrated in FIG. 3, a terminal section TS, which includes a plurality of terminals TM for connection to external circuits, is provided outside the first side 23a of the bank 23. At least the terminals TM of the terminal section TS are free of the seal portion 5 (first sealing film 26, coupling layer 30, second sealing film 27, and third sealing film 33).

In the present embodiment, a distance D, which is between the first side 23a (side adjacent to the terminal section TS) of the bank 23 and the edge 30e of the coupling layer 30, is greater than a distance d, which is between the third side 23c (side free of the terminal section TS) of the bank 23 and the edge 30e of the coupling layer 30.

Furthermore, a distance X, which is between the second side 23b (side adjacent to the wiring section FS) of the bank 23 and the display area DA is greater than a distance x, which is between the first side 23a (side adjacent to the terminal section TS) of the bank 23 and the display area DA.

An apparatus for producing an OLED panel performs, for example, the following steps to produce the OLED panel 2, which is flexible (see FIGS. 1 to 4).

First, a backplane is formed. The backplane includes, on a glass substrate, the resin layer 13, the moisture-proof layer 14, the semiconductor films 15, the gate insulator film 16, a first metal layer including the gate electrodes G, the first interlayer insulating film 18, a second metal layer including the capacitive electrodes C, the second interlayer insulating film 20, a third metal layer including the source electrodes S, the drain electrodes D, and the wires W, the flattering film 21, and the anode electrodes 22. Next, the organic EL layers 24 and the cathode electrodes 25 are formed on the backplane. Next, the seal portion 5, which includes the coupling layer 30, is formed to cover the OLED elements 4 (see FIG. 4 for details). Next, a protective film is applied to the seal portion 5, and the glass substrate is removed by, for example, laser irradiation. The flexible base substrate 11 is applied to the resin layer 13 via the adhesive layer 12. Thus, the flexible OLED panel 2 is obtained. The protective film on the seal portion 5 can be removed, and the functional panel 6 can be attached to the seal portion 5 of the OLED panel 2 via the adhesive layer 8. In this manner, the display device 10 can be obtained.

In the present embodiment, the coupling layer 30, which has an affinity for organic films and inorganic films, is formed on the first sealing film 26, which is an inorganic film, and the second sealing film 27, which is an organic film, is formed by applying ink including an organic photosensitive material to the coupling layer 30 by an ink-jet method and curing the ink with UV light.

As a result of applying ink droplets to the coupling layer 30 as described above, the wettability of the droplets increases. Consequently, the second sealing film 27 can be easily formed to a desired shape (e.g., thickness and area). Also, the bond between the first sealing film 26 and the second sealing film 27 increases via the coupling layer 30. Accordingly, the sealing performance can be enhanced.

The coupling layer 30 is formed to extend outside the display area DA (into the non-display area), but the edge 30e of the coupling layer 30 is located inside the bank 23 so that a predetermined distance d is provided between the edge of the coupling layer 30 and the bank 23. As a result, while the wettability of the droplets increases on the coupling layer 30, the wettability of the droplets does not increase on the area between the edge of the coupling layer 30 and the bank 23. Thus, the possibility that the droplets will spread beyond the bank 23 is reduced. Consequently, the distance between the edge of the panel and the bank 23 can be reduced, the distance between the terminal section TS and the bank 23 (first side 23a thereof) can be reduced, and the bank 23 can be of a single-walled construction (not double- or more than double-walled construction). As a result, frame narrowing is achieved.

The distance D between the first side 23a (side adjacent to the terminal section TS) of the bank 23 and the edge 30e of the coupling layer 30 is greater than the distance d between the third side 23c (side free of the terminal section TS) of the bank 23 and the edge 30e of the coupling layer 30. This configuration reduces the possibility that the droplets will spread beyond the bank 23 and enter into the terminal section TS (possibility that the second sealing film 27 will be formed on the terminal section TS).

In the present embodiment, the first sealing film 26 is patterned by performing CVD film forming through a mask (e.g., metal mask). Furthermore, the coupling layer 30 is also patterned by performing CVD film forming through a mask (e.g., metal mask). The use of CVD film forming results in increased coverage, and as a result, can reduce convex and recess due to, for example, wires in a lower layer.

For example, since the coupling layer 30 overlaps the wiring section FS (the coupling layer 30 covers the wiring section wires Hj via the first sealing film 26), convex and recess attributable to the wiring section wires Hj can be reduced. As a result of this, in combination with the liquid-philic behavior of the coupling layer 30, the droplets will spread sufficiently over the area on the wiring section FS, too.

The flattering film 21 is not present on the wiring section FS. Thus, in a case where the coupling layer 30 is not present, the droplets may travel within narrow grooves formed by the wiring section wires Hj in the surface of the first sealing film 26 and may spread beyond the bank. However, the presence of the coupling layer 30 reduces the possibility.

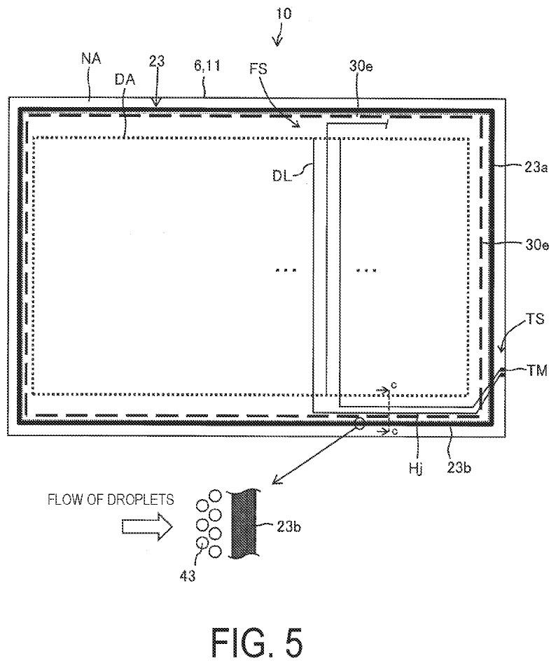

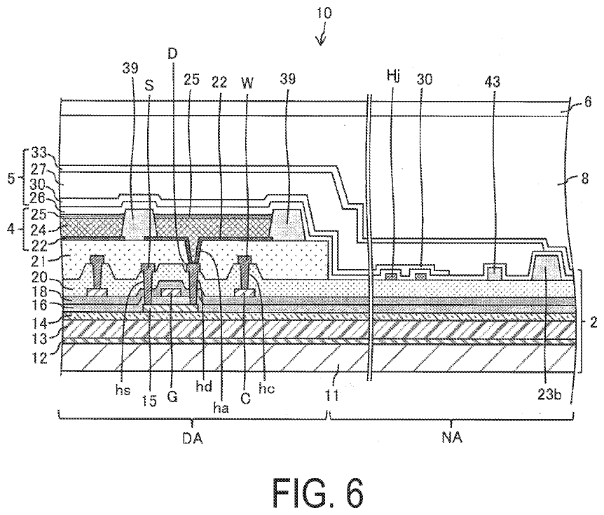

FIG. 5 is a plan view illustrating another configuration of the display device according to the present embodiment. FIG. 6 is a cross-sectional view of the display device of FIG. 5 taken along line c-c and viewed in the direction of the arrows.

As illustrated in FIGS. 5 and 6, a plurality of buffers 43 may be provided in a staggered arrangement in front of the bank 23 (particularly, first side 23a, which is adjacent to the terminal section TS). Here, the term “in front of” means the side closer to the display area. This configuration inhibits the flow of the droplets and thus reduces the possibility that the droplets will spread beyond the bank 23 (particularly, enter into the terminal section TS).

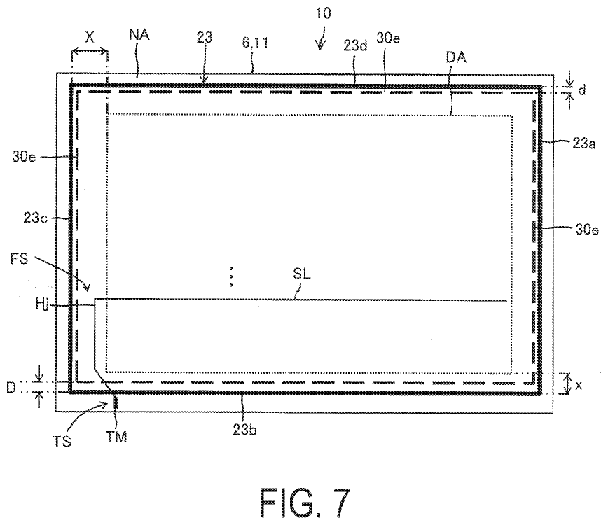

In FIGS. 1 and 5, the terminal section TS is provided outside the first side 23a (short side) of the bank 23, and the wiring section FS is provided inside the second side 23b (long side) of the bank 23. However, this is merely illustrative. As illustrated in FIG. 7, the terminal section TS may be provided outside the second side 23b (long side) of the bank 23, and a wiring section FS for routing scanning lines SL may be provided inside the third side 23c (short side) of the bank 23.

In the configuration of FIG. 7, too, the distance D between the second side 23b (side adjacent to the terminal section TS) of the bank 23 and the edge 30e of the coupling layer 30 is greater than the distance d between the fourth side 23d (side free of the terminal section TS) of the bank 23 and the edge 30e of the coupling layer 30.

Furthermore, a distance X between the third side 23c (side adjacent to the wiring section FS) of the bank 23 and the display area DA is greater than a distance x between the second side 23b (side adjacent to the terminal section TS) of the bank 23 and the display area DA.

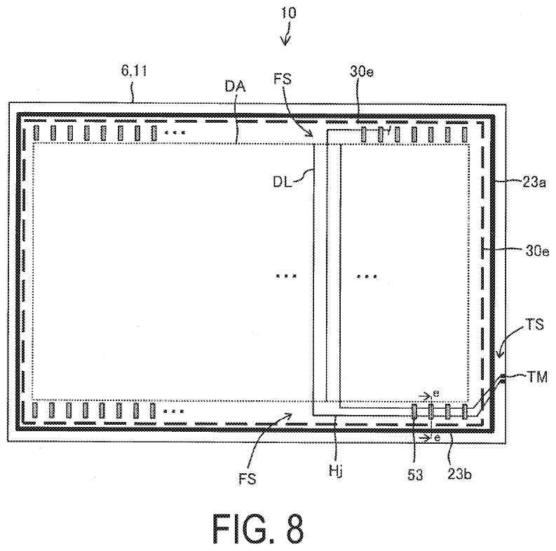

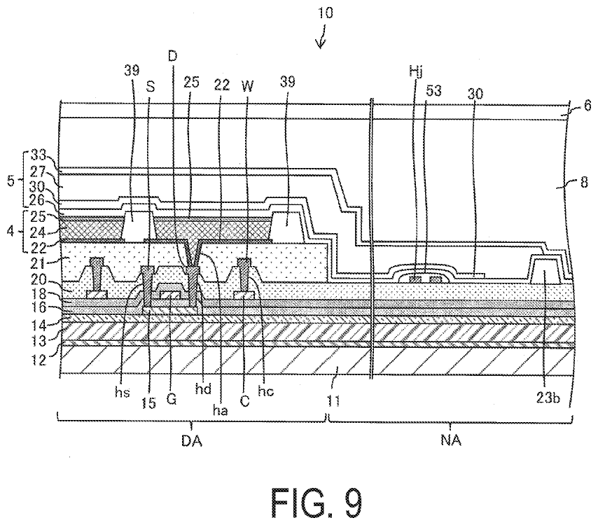

FIG. 8 is a plan view illustrating still another configuration of the display device according to the present embodiment. FIG. 9 is a cross-sectional view of the display device of FIG. 8 taken along line e-e and viewed in the direction of the arrows.

As illustrated in FIGS. 8 and 9, a plurality of ribs 53, each extending in the column direction, may be provided on the wiring section FS, along the second side 23b of the bank 23. The coupling layer 30 may be formed to overlap all the ribs 53. That is, the coupling layer 30 covers the ribs 53 via the first sealing film 26. As a result of this configuration, the coupling layer 30 has, in the wiring section FS, an irregular surface portion due to the ribs 53. Thus, the surface tension of the irregular surface portion, in combination with the liquid-philic behavior of the coupling layer 30, facilitates spreading of the droplets.

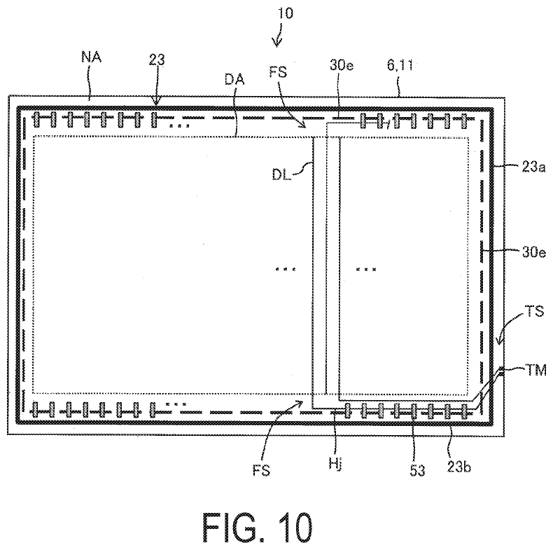

As illustrated in FIG. 10, the edge 30e of the coupling layer 30 may overlap the ribs 53. That is, the coupling layer 30 may be formed to overlap a portion (inner portion) of each of the ribs 53 and not to overlap the remaining portion (outer portion). This configuration facilitates spreading of the droplets in the portion, of the irregular surface portion, that overlaps the coupling layer 30 (inner side) and impedes spreading of the droplets in the portion, of the irregular surface portion, that does not overlap the coupling layer 30 (outer side). As a result, the formation position for the second sealing film 27 (position of the edge 30e) can be controlled with high accuracy. Consequently, frame narrowing is achieved.

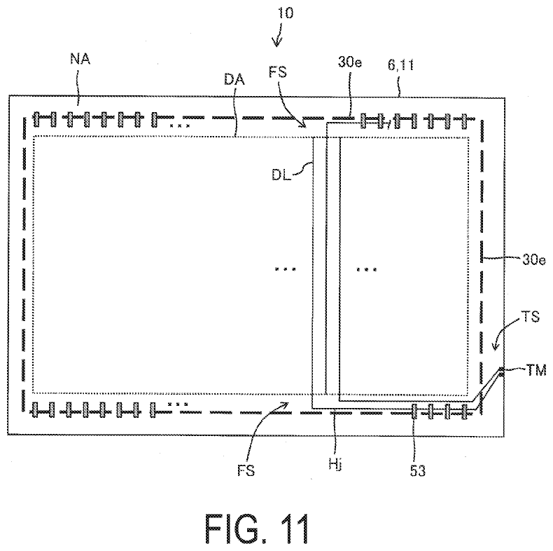

Furthermore, as illustrated in FIG. 11, the bank may be eliminated (may not be formed). This configuration is possible because the edge 30e of the coupling layer 30 is disposed so as to overlap the ribs 53 and thus the formation position for the second sealing film 27 (position of the edge 30e) is controlled with high accuracy.

### Supplement

In a first aspect, an OLED panel includes a base substrate, an OLED element and a seal portion covering the OLED element. The seal portion includes a first sealing film including an inorganic film, a second sealing film including an organic film, a third sealing film including an inorganic film, and a coupling layer formed between the first sealing film and the second sealing film. The OLED panel is not limited to use in display devices, and is applicable to electronic devices (e.g., detection devices) that use OLEDs as photodiodes or temperature sensors, for example.

In a second aspect, the second sealing film includes an organic material coatable by an ink-jet method.

In a third aspect, a bank is provided outside a display area including the OLED element. The bank defines an edge of the second sealing film. The coupling layer includes an edge, and the edge is located outside the display area and inside the bank. A predetermined distance is provided between the edge of the coupling layer and the bank.

In a fourth aspect, the bank has a frame shape, and a terminal section is provided outside a first side of the bank.

In a fifth aspect, a wiring section is provided to route wires. The wiring section is located outside the display area and inside a second side of the bank. The coupling layer overlaps the wiring section.

In a sixth aspect, a distance between the second side of the bank and the display area is greater than a distance between the first side of the bank and the display area.

In a seventh aspect, a plurality of ribs are disposed side by side on the wiring section, and the coupling layer overlaps the plurality of ribs.

In an eighth aspect, the coupling layer overlaps a portion of each of the plurality of ribs and does not overlap a remaining portion of each of the plurality of ribs.

In a ninth aspect, a distance between the first side of the bank and the edge of the coupling layer is greater than a distance between a third side of the bank and the edge of the coupling layer, the third side being free of the terminal section.

In a tenth aspect, the bank has a single-walled frame shape.

In an eleventh aspect, the coupling layer includes a material formable into the coupling layer by CVD.

In a twelfth aspect, the material includes an organosilicon compound.

In a thirteenth aspect, the organosilicon compound includes hexamethyldisiloxane or silicon carbon nitride.

In a fourteenth aspect, the base substrate is flexible.

In a fifteenth aspect, a plurality of ribs are disposed side by side in a non-display area, the non-display area being free of the OLED elements, and the coupling layer overlaps the plurality of ribs.

In a sixteenth aspect, the coupling layer has an affinity for an inorganic film and an organic film.

In a seventeenth aspect, a method for producing an OLED panel is provided. The OLED panel includes a base substrate, an OLED element, and a seal portion. The seal portion includes a first sealing film including an inorganic film and a second sealing film including an organic film. The method includes forming a coupling layer on the first sealing film, and forming, by an ink-jet method, the second sealing film on the coupling layer.

In an eighteenth aspect, the coupling layer is formed including an edge, and the edge is located outside a display area and inside a bank. The display area includes the OLED element. The bank defines an edge of the second sealing film. A predetermined distance is provided between the edge of the coupling layer and the bank.

In a nineteenth aspect, the coupling layer is patterned by CVD through a mask.

In a twentieth aspect, the first sealing film is patterned by CVD through a mask.

In a twenty-first aspect, the coupling layer includes an organosilicon compound.

In a twenty-second aspect, the organosilicon compound is hexamethyldisiloxane or silicon carbon nitride.

In a twenty-third aspect, an apparatus for producing an OLED panel is provided. The OLED panel includes a base substrate, an OLED element, and a seal portion. The seal portion includes a first sealing film including an inorganic film and a second sealing film including an organic film. The apparatus is configured to form a coupling layer on the first sealing film and form, by an ink-jet method, the second sealing film on the coupling layer.

### Remarks

The disclosure is not limited to the embodiments described above, and includes embodiments that can be implemented by combining techniques disclosed in different embodiments and includes embodiments that can be implemented by combining techniques disclosed in different drawings (any combination of the techniques disclosed in the drawings, FIGS. 1 to 11).

### REFERENCE SIGNS LIST

2 OLED panel
4 OLED element
5 Seal portion
23 Bank
26 First sealing film
27 Second sealing film
30 Coupling layer
33 Third sealing film
39 Partition
43 Buffer
53 Rib
FS Wiring section
TS Terminal section
DA Display area
NA Non-display area
Hj Wiring section wire

1. An OLED panel comprising:
a base substrate;
an OLED element; and
a seal portion covering the OLED element, the seal portion including:
a first sealing film including an inorganic film;
a second sealing film including an organic film;
a third sealing film including an inorganic film; and
a coupling layer formed between the first sealing film and the second sealing film,
wherein a bank is provided outside a display area including the OLED element, the bank defining an edge of the second sealing film,
the coupling layer includes an edge, and the edge is formed outside the display area and inside the bank, and
a predetermined distance is provided between the edge of the coupling layer and the bank.

2. The OLED panel according to claim 1,
wherein the second sealing film includes an organic material coatable by an ink-jet method.

3. (canceled)

4. The OLED panel according to claim 1,
wherein the bank has a frame shape, and a terminal section is provided outside a first side of the bank.

5. The OLED panel according to claim 4,
wherein a wiring section is provided to route wires,
the wiring section is located outside the display area and inside a second side of the bank, and
the coupling layer overlaps the wiring section.

6. The OLED panel according to claim 5,
wherein a distance between the second side of the bank and the display area is greater than a distance between the first side of the bank and the display area.

7. The OLED panel according to claim 5,
wherein a plurality of ribs are disposed side by side on the wiring section, and the coupling layer overlaps the plurality of ribs.

8. The OLED panel according to claim 7,
wherein the coupling layer overlaps a portion of each of the plurality of ribs and does not overlap a remaining portion of each of the plurality of ribs.

9. The OLED panel according to claim 5,
wherein a distance between the first side of the bank and the edge of the coupling layer is greater than a distance between a third side of the bank and the edge of the coupling layer, the third side being free of the terminal section.

10. The OLED panel according to claim 1,
wherein the bank has a single-walled frame shape.

11. The OLED panel according to claim 1,
wherein the coupling layer includes a material formable into the coupling layer by CVD.

12. The OLED panel according to claim 11,
wherein the material includes an organosilicon compound.

13. The OLED panel according to claim 12,
wherein the organosilicon compound includes hexamethyldisiloxane or silicon carbon nitride.

14. The OLED panel according to claim 1,
wherein the base substrate is flexible.

15. The OLED panel according to claim 1,
wherein a plurality of ribs are disposed side by side in a non-display area, the non-display area being free of the OLED element, and
the coupling layer overlaps the plurality of ribs.

16. The OLED panel according to claim 15,
wherein wiring section wires are provided to route wires of the display area, the display area including the OLED element, and
the wiring section wires overlap the plurality of ribs.

17. The OLED panel according to claim 1,
wherein the coupling layer has an affinity for an inorganic film and an organic film.

18. A method for producing an OLED panel, the OLED panel including a base substrate, an OLED element, and a seal portion, the seal portion including a first sealing film including an inorganic film and a second sealing film including an organic film, the method comprising: forming a coupling layer on the first sealing film; and
forming the second sealing film on the coupling layer by an ink-jet method,
wherein the coupling layer is formed including an edge, and the edge is located outside a display area and inside a bank, the display area including the OLED elements, the bank defining an edge of the second sealing film, and
a predetermined distance is provided between the edge of the coupling layer and the bank.

19. (canceled)

20. The method for producing an OLED panel according to claim 18,
wherein the coupling layer is patterned by CVD through a mask.

21. The method for producing an OLED panel according to any one of claims 18,
wherein the first sealing film is patterned by CVD through a mask.

22. The method for producing an OLED panel according to claim 20,
wherein the coupling layer includes an organosilicon compound.

23-24. (canceled)
